(19) United States
(12) Patent Application Publication
(10) Pub. No.: US 2026/0182259 A1
(43) Pub. Date: Jun. 25, 2026

(54) SEMICONDUCTOR DEVICE INCLUDING CHANNEL STRUCTURE INCLUDING RESISTANCE CHANGE LAYER

(71) Applicant: SK hynix Inc., Icheon-si (KR)

(72) Inventors: Won Tae KOO, Icheon-si (KR); Pil Hoon JUNG, Icheon-si (KR)

(21) Appl. No.: 19/232,768

(22) Filed: Jun. 9, 2025

(30) Foreign Application Priority Data
Dec. 23, 2024 (KR) 10-2024-0194785

(51) Int. Cl. H10N 70/20; H10B 63/00; H10N 70/00

(52) U.S. Cl. CPC H10N 70/253; H10B 63/00; H10N 70/24; H10N 70/823; H10N 70/826; H10N 70/8833; H10N 70/8836

(57) ABSTRACT

A semiconductor device includes a substrate, a channel structure disposed over the substrate, a source electrode layer and a drain electrode layer respectively disposed at opposite ends of the channel structure, an oxygen vacancy reservoir layer disposed on the channel structure, and a gate electrode layer disposed on the oxygen vacancy reservoir layer. The channel structure includes a base channel layer, a barrier layer, and a resistance change layer sequentially disposed over the substrate.

### CROSS-REFERENCE TO RELATED APPLICATION

The present application claims priority under 35 U.S. C § 119(a) to Korean Application No. 10-2024-0194785, filed in the Korean Intellectual Property Office on Dec. 23, 2024, which is incorporated herein by reference in its entirety.

### BACKGROUND

### 1. Technical Field

The present disclosure generally relates to a semiconductor device including a resistance change layer.

### 2. Related Art

Recently, electrochemical random access memory (ECRAM) devices have been proposed. ECRAM devices are memory devices formed using memory technology that stores information by utilizing an electrochemical reaction. ECRAM devices are differentiated in their operations from conventional flash memory devices, ferroelectric memory devices, or magnetic memory devices in that the ECRAM devices operate based on the modulation of ion states within a constituent material. Due to the unique operational characteristics that result from the modulation of ion states, ECRAM devices are attracting attention from the industry as memory devices capable of implementing a high level of energy efficiency.

### SUMMARY

The present disclosure describes a memory device that may include a substrate, a channel structure disposed over the substrate, a source electrode layer and a drain electrode layer respectively disposed at opposite ends of the channel structure, an oxygen vacancy reservoir layer disposed on the channel structure, and a gate electrode layer disposed on the oxygen vacancy reservoir layer. The channel structure may include a base channel layer, a barrier layer, and a resistance change layer sequentially disposed over the substrate.

The present disclosure describes a memory device that may include a substrate, a gate structure disposed over the substrate, a hole pattern penetrating the gate structure and exposing a sidewall surface of the gate structure, an oxygen vacancy reservoir layer disposed within the hole pattern and covering the sidewall surface of the gate structure, and a channel structure disposed within the hole pattern and contacting the oxygen vacancy reservoir layer. The gate structure may include at least one gate electrode layer and at least one interlayer insulating layer that are alternatively stacked. The channel structure may include a base channel layer, a barrier layer, and a resistance change layer, which are sequentially disposed on the oxygen vacancy reservoir layer.

### BRIEF DESCRIPTION OF THE DRAWINGS

FIG. 1 schematically illustrates a semiconductor device according to an embodiment of the present disclosure.

FIG. 2 is a circuit diagram of a channel structure of a semiconductor device of FIG. 1.

FIG. 3A and FIG. 3B schematically illustrate a write operation of a semiconductor device according to an embodiment of the present disclosure.

FIG. 4A and FIG. 4B schematically illustrate a write operation of a semiconductor device according to a comparative example.

FIG. 5 illustrates changes in conductance of channel structures over time after completion of a writing operation.

FIG. 6 is a cross-sectional view schematically illustrating a semiconductor device according to another embodiment of the present disclosure.

FIG. 7 is a perspective view schematically illustrating a semiconductor device according to another embodiment of the present disclosure.

FIG. 8 is a cross-sectional view of the semiconductor device of FIG. 7 taken along a line I-I′.

FIG. 9 is a circuit diagram of a semiconductor device according to an embodiment of the present disclosure.

FIG. 10 is a perspective view schematically illustrating a semiconductor device according to another embodiment of the present disclosure.

FIG. 11 is a cross-sectional view of the semiconductor device of FIG. 10 taken along a line II-II′.

### DETAILED DESCRIPTION

Hereinafter, embodiments of the present disclosure will be described in detail with reference to the accompanying drawings. In the drawings, in order to clearly express the components of each device, the sizes of the components, such as width and thickness of the components, are enlarged. The cross-hatching throughout the figures illustrates corresponding or similar areas among the figures rather than indicating the materials associated with the areas.

The terms used herein may correspond to words selected in consideration of their functions in the embodiments, and the meanings of the terms may be construed to be different according to the ordinary skill in the art to which the embodiments belong. If expressly defined in detail, the terms may be construed according to the definitions. Unless otherwise defined, the terms (including technical and scientific terms) used herein have the same meaning as commonly understood by one of ordinary skill in the art to which the embodiments belong.

In addition, expression of a singular form of a word should be understood to include the plural forms of the word unless clearly used otherwise in the context. It will be understood that the terms “comprise,” “include,” or “have” are intended to specify the presence of a feature, a number, a step, an operation, a component, an element, a part, or combinations thereof, but not used to preclude the presence or possibility of addition one or more other features, numbers, steps, operations, components, elements, parts, or combinations thereof.

Terms used in the specification of the present application are terms selected in consideration of functions in the presented embodiments, and the meaning of the terms may vary depending on the intention or custom of a user or operator in the technical field. The meanings of the terms used follow the definitions defined when specifically defined herein, and may be interpreted as meanings generally recognized by those skilled in the art in the absence of specific definitions.

In this specification, a write operation of a semiconductor device includes a set operation and a reset operation. The set operation is an operation of increasing conductance of a resistance change layer (or an operation of decreasing electrical resistance). The resistance change layer may maintain the increased conductance even after the set operation is completed. Accordingly, the semiconductor device can non-volatilely store signal information corresponding to the increased conductance. The reset operation is an operation of decreasing the conductance of the resistance change layer (or an operation of increasing the electrical resistance). The resistance change layer can maintain the decreased conductance even after the reset operation is completed. Accordingly, the semiconductor device can store signal information in a non-volatile manner corresponding to the decreased conductance.

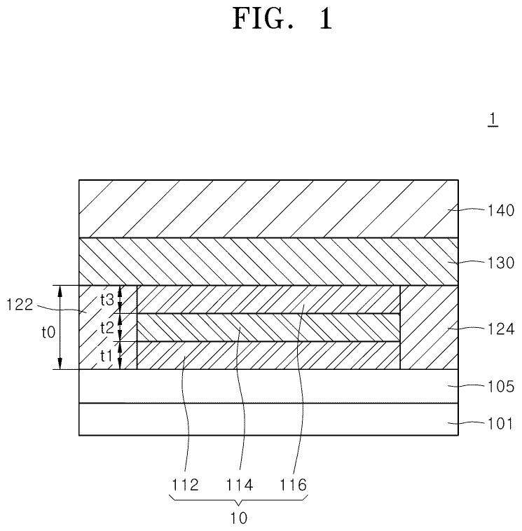

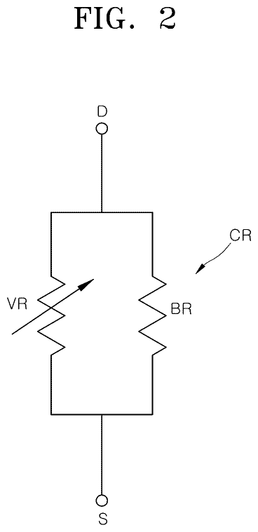

FIG. 1 schematically illustrates a semiconductor device according to an embodiment of the present disclosure. FIG. 2 is a circuit diagram of a channel structure of a semiconductor device of FIG. 1.

Referring to FIG. 1, a semiconductor device 1 includes a substrate 101, a channel structure 10 disposed over the substrate 101, a source electrode layer 122 and a drain electrode layer 124 disposed at opposite ends of the channel structure 10, an oxygen vacancy reservoir layer 130 disposed on the channel structure 10, and a gate electrode layer 140 disposed on the oxygen vacancy reservoir layer 130. The channel structure 10 includes a base channel layer 112, a barrier layer 114, and a resistance change layer 116 that are sequentially stacked over the substrate 101.

Referring to FIG. 1, the substrate 101 includes a conductor, a semiconductor, or an insulator capable of being subjected to semiconductor integration processes. In an embodiment, the substrate 101 is a semiconductor substrate. Specifically, the semiconductor substrate includes, for example, silicon (Si), germanium (Ge), gallium arsenide (GaAs), molybdenum selenide (MoSe₂), hafnium selenide (HfSe₂), indium selenide (InSe), gallium selenide (GaSe), black phosphorous, indium-gallium-zinc oxide (IGZO), or a combination of two or more thereof. The semiconductor substrate may be doped with a dopant. The semiconductor substrate may be doped, for example, with an N-type dopant or a P-type dopant.

Referring to FIG. 1, a base insulating layer 105 is disposed on the substrate 101. The base insulating layer 105 electrically insulates the substrate 101 and the channel structure from each other. The base insulating layer 105 includes an insulating material. The insulating material includes, for example, oxide, nitride, oxynitride, or a combination of two or more thereof.

The channel structure 10 is disposed on the base insulating layer 105. As illustrated in FIG. 1, the base channel layer 112 of a thickness t1 is disposed on the base insulating layer 105. The barrier layer 114 of a thickness t2 is disposed on the base channel layer 112. The resistance change layer 116 of a thickness t3 is disposed on the barrier layer 114.

The base channel layer 112 includes oxygen vacancies. The base channel layer 112 has a conductance value proportional to concentration of oxygen vacancies. As described below, the concentration of oxygen vacancies in the base channel layer 112, as compared to the resistance change layer 116, may not change through a write operation of the semiconductor device 1. Accordingly, the conductance of the base channel layer 112 may not change through the write operation of the semiconductor device 1. As an example, the base channel layer 112 may have a fixed conductance value.

The base channel layer 112 includes metal oxide containing oxygen vacancies. The metal oxide may be, for example, perovskite oxide. Composition of the metal oxide may not satisfy the stoichiometric ratio between metal and oxygen. The base channel layer 112 includes, for example, tungsten oxide (WO₃), molybdenum oxide (MoO₃), selenium oxide (CeO₃), iron oxide (Fe₃O₄), zirconium oxide (ZrO₂), cobalt oxide (CoO), vanadium oxide (V2O₅), titanium oxide (TiO₂), strontium titanium oxide (SrTiO₃), yttrium oxide (Y₂O₃), indium gallium zinc oxide (InGaZnO), or a combination of two or more thereof. The base channel layer 112 has a thickness t1 of, for example, 1 nm to 10 nm.

The barrier layer 114 functions to suppress the movement of oxygen between the base channel layer 112 and the resistance change layer 116. The barrier layer 114 suppresses the exchange of oxygen vacancies between the base channel layer 112 and the resistance change layer 116. The barrier layer 114 includes a covalent bonding material, and thus has a dense crystal structure. As a result, the barrier layer 114 can suppress oxygen ions or oxygen atoms from passing through the barrier layer 114. As an example, the barrier layer 114 can inhibit the oxygen ions from conducting between the base channel layer 112 and the resistance change layer 116 when an electric field is formed between the base channel layer 112 and the resistance change layer 116. As another example, the barrier layer 114 can inhibit the oxygen ions or the oxygen atoms from diffusing between the base channel layer 112 and the resistance change layer 116 when a concentration gradient of the oxygen ions or the oxygen atoms is formed between the base channel layer 112 and the resistance change layer 116. The barrier layer 114 includes, for example, silicon oxide, silicon nitride, silicon oxynitride, aluminum oxide, aluminum nitride, or a combination of two or more thereof. The barrier layer 114 has a thickness t2 of, for example, 3 nm to 10 nm.

The resistance change layer 116 includes oxygen vacancies. The resistance change layer 116 has conductance that changes depending on the concentration of the oxygen vacancies therein. The resistance change layer 116 includes metal oxide including oxygen vacancies. The metal oxide may be, for example, perovskite oxide. The composition of the metal oxide may not satisfy the stoichiometric ratio between the metal and oxygen. The resistance change layer 116 includes, for example, tungsten oxide (WO₃), molybdenum oxide (MoO₃), selenium oxide (CeO₃), iron oxide (Fe₃O₄), zirconium oxide (ZrO₂), cobalt oxide (CoO), vanadium oxide (V₂O₅), titanium oxide (TiO₂), strontium titanium oxide (SrTiO₃), yttrium oxide (Y₂O₃), indium gallium zinc oxide (InGaZnO), or a combination of two or more thereof. In an embodiment, the resistance change layer 116 may include substantially the same material as the base channel layer 112. The resistance change layer 116 has a thickness t3 of, for example, 1 nm to 3 nm. The thickness t3 of the resistance change layer 116 may be smaller than the thickness t1 of the base channel layer 112.

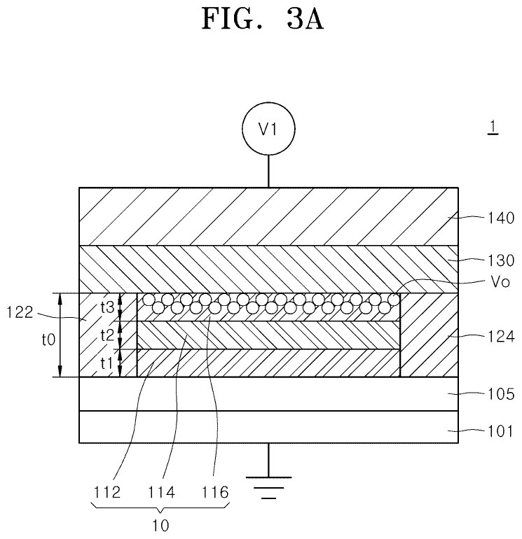

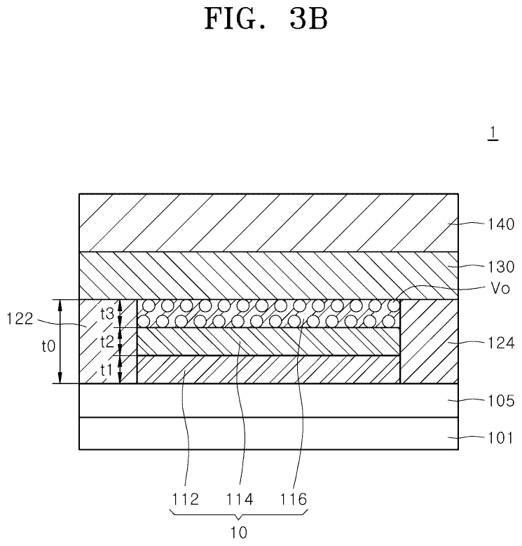

As described below with reference to FIG. 3A and FIG. 3B, when a write voltage such as a set voltage or a reset voltage is applied between the gate electrode layer 140 and the substrate 101, the resistance change layer 116 exchanges oxygen vacancies with the oxygen vacancy reservoir layer 130. After the write voltage is removed, the conductance of the resistance change layer 116 can be determined as proportional to the concentration of the oxygen vacancies remaining in the resistance change layer 116. On the other hand, the base channel layer 112 is suppressed from exchanging oxygen vacancies with the resistance change layer 116 by the barrier layer 114. Accordingly, the base channel layer 112 is inhibited from exchanging the oxygen vacancies with the oxygen vacancy reservoir layer 130 via the resistance change layer 116. The base channel layer 112 can have an invariable concentration of oxygen vacancy, regardless of the application of the write voltage. Due to the fixed concentration of oxygen vacancies, the base channel layer 112 can have an invariable conductance, for example, a fixed conductance value.

Referring to FIG. 1, the source electrode layer 122 and the drain electrode layer 124 are respectively disposed at opposite ends of the channel structure 10 over the base insulating layer 105. Each of the source electrode layer 122 and the drain electrode layer 124 includes a conductive material. The conductive material includes, for example, a doped semiconductor, metal, conductive metal nitride, conductive metal carbide, conductive metal silicide, or a conductive metal oxide. The conductive material includes, for example, silicon (Si) doped with an n-type dopant or a p-type dopant, tungsten (W), titanium (Ti), copper (Cu), aluminum (Al), ruthenium (Ru), platinum (Pt), iridium (Ir), iridium oxide, tungsten nitride, titanium nitride, tantalum nitride, tungsten carbide, titanium carbide, tungsten silicide, titanium silicide, tantalum silicide, ruthenium oxide or a combination of two or more thereof.

The source electrode layer 122, the drain electrode layer 124, and the channel structure 10 have substantially the same thickness t0. Upper surfaces of the source electrode layer 122, the drain electrode layer 124, and the resistance change layer 116 are positioned at substantially the same level.

The oxygen vacancy reservoir layer 130 is disposed on the channel structure 10. The oxygen vacancy reservoir layer 130 is disposed to cover the upper surfaces of the source electrode layer 122, the channel structure 10, and the drain electrode layer 124.

The oxygen vacancy reservoir layer 130 includes oxide having oxygen vacancies. The oxygen vacancy reservoir layer 130 includes, for example, gadolinium oxide (GdOₓ(0<x≤1)), molybdenum oxide (MoOₓ(0<x≤1)), tungsten oxide (WO₃₋ₓ(0<x≤1)), copper oxide (CuO), titanium oxide (TiO₂), or a combination of two or more thereof.

While a write operation such as a set operation or a reset operation is in progress, the oxygen vacancy reservoir layer 130 exchanges oxygen vacancies with the resistance change layer 116 of the channel structure 10. As an example, when a set voltage is applied between the gate electrode layer 140 and the substrate 101, the oxygen vacancy reservoir layer 130 provides oxygen vacancies to the resistance change layer 116, thereby increasing the concentration of the oxygen vacancies inside the resistance change layer 116. As another example, when a reset voltage is applied between the gate electrode layer 140 and the substrate 101, the oxygen vacancy reservoir layer 130 receives oxygen vacancies from the resistance change layer 116, thereby decreasing the concentration of the oxygen vacancy inside the resistance change layer 116.

The gate electrode layer 140 is disposed on the oxygen vacancy reservoir layer 130. The gate electrode layer 140 includes a conductive material. The conductive material may include, for example, a doped semiconductor, metal, conductive metal nitride, conductive metal carbide, conductive metal silicide, or conductive metal oxide.

In some embodiments, unlike that illustrated in FIG. 1, the oxygen vacancy reservoir layer 130 may be positioned only directly on the channel structure 10. That is, the oxygen vacancy reservoir layer 130 may not cover the upper surfaces of the source electrode layer 122 and the drain electrode layer 124. In addition, the gate electrode layer 140 is disposed only directly on the oxygen vacancy reservoir layer 130, and the gate electrode layer 140 is electrically isolated from the source electrode layer 122 and the drain electrode layer 124.

In an embodiment of the present disclosure, the source electrode layer 122, the drain electrode layer 124, and the channel structure 10 of the semiconductor device 1 correspond to a source terminal S, a drain terminal D, and a channel resistor device CR in the circuit diagram of FIG. 2, respectively. The base channel layer 112 and the resistance change layer 116 of the channel structure 10 correspond to a base resistance element BR and a variable resistance element VR of the channel resistance device CR of FIG. 2, respectively. In this manner, the base channel layer 112 and the resistance change layer 116 may form an electrical parallel circuit between the source electrode layer 122 and the drain electrode layer 124.

Referring to FIG. 1 and FIG. 2 together, between the source electrode layer 122 and the drain electrode layer 124, channel conductance of the channel structure 10 is determined by a combination of the conductance of the base channel layer 112 and the conductance of the resistance change layer 116. Based on the circuit diagram of FIG. 2, the conductance of the channel structure 10 changes as the conductance of the resistance change layer 116 changes.

In an embodiment, the resistance change layer 116 has distinct resistance states, that is, a high resistance state and a low resistance state. In the high resistance state, the resistance change layer 116 has a conductance value substantially equal to the conductance value of the base channel layer 112. In this case, based on the circuit diagram of FIG. 2, the channel structure 10 has a conductance value corresponding to twice the conductance value of the base channel layer 112 or the resistance change layer 116. The semiconductor device 1 stores the channel conductance value of the channel structure 10 as first signal information when the resistance change layer 116 is in the high resistance state.

In the low resistance state, the resistance change layer 116 has a conductance value corresponding to 10 to 100 times greater than the conductance value of the base channel layer 112. In this case, based on the circuit diagram of FIG. 2, the channel structure 10 has a channel conductance value corresponding to 11 to 101 times greater than the conductance value of the base channel layer 112. In addition, the channel conductance value of the channel structure 10 when the resistance change layer 116 is in the low resistance state may correspond to 5.5 to 50.5 times the channel conductance value of the channel structure 10 when the resistance change layer 116 is in the high resistance state. The semiconductor device 1 stores the channel conductance value of the channel structure 10 as second signal information when the resistance change layer 116 is in the low resistance state.

In an embodiment, the conductance of the resistance change layer 116 when the resistance change layer 116 is in the low resistance state can be implemented as a plurality of conductance values that are distinguishable or distinct from each other. The channel structure 10 is controlled to have a plurality of channel conductance values that are measurably distinguishable or distinct from each other in response to the plurality of conductance values of the resistance change layer 116. As a result, the semiconductor device 1 can store a plurality of distinguishable and readable levels of signal information corresponding to the plurality of channel conductance values of the channel structure 10.

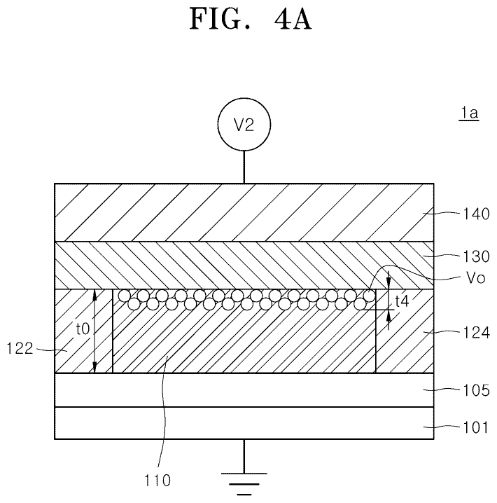

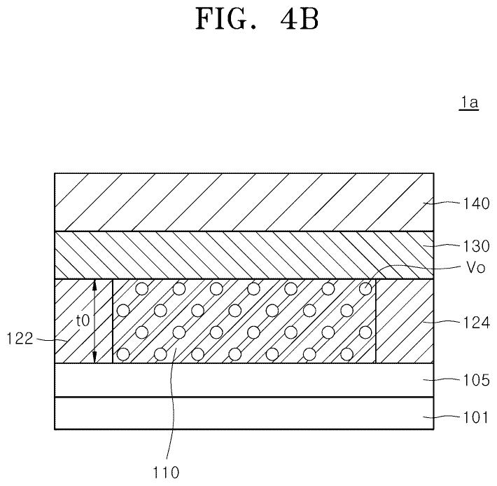

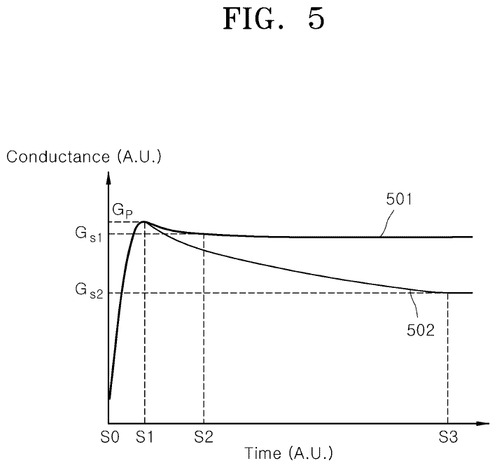

FIG. 3A and FIG. 3B schematically illustrate a write operation of a semiconductor device according to an embodiment of the present disclosure. FIG. 4A and FIG. 4B schematically illustrate a write operation of a semiconductor device according to a comparative example. FIG. 5 illustrates changes in conductance values of channel structures over time after completion of a write operation.

A write operation of a semiconductor device in FIG. 3A and FIG. 3B is explained with reference to a semiconductor device 1 of FIG. 1. A write operation of a semiconductor device in FIG. 4A and FIG. 4B is explained with reference to a semiconductor device 1a according to a comparative example. As illustrated in FIG. 4A and FIG. 4B, a configuration of a semiconductor device 1a of the comparative example is substantially the same as the configuration of a semiconductor device 1 of disclosed embodiments, except for a configuration of channel layer 110. The channel layer 110 according to the comparative example is differentiated from a channel structure 10 according to disclosed embodiments in that the channel layer 110 is a single resistance change material layer. The material of the channel layer 110 according to the comparative example may be substantially the same as the material of a resistance change layer 116 of the channel structure 10 according to an embodiment as illustrated in FIG. 1. A thickness t0 of the channel structure 10 of FIGS. 3A and 3B and a thickness t0 of the channel layer 110 of FIGS. 4A and 4B may be substantially the same.

Referring to FIG. 3A, a set operation is performed by applying a first set voltage between a gate electrode layer 140 and a substrate 101. In an embodiment, the first set voltage is applied by grounding the substrate 101 and applying a first potential V1 of a positive polarity to the gate electrode layer 140.

Along an electric field formed by applying the first set voltage, oxygen inside a resistance change layer 116 moves to an oxygen vacancy reservoir layer 130 in the form of ions. As the oxygen moves from the resistance change layer 116 to the oxygen vacancy reservoir layer 130, oxygen vacancies Vo are generated in the resistance change layer 116. The movement of the oxygen may occur relatively preferentially in a region of the resistance change layer 116 adjacent to an interface with the oxygen vacancy reservoir layer 130. Accordingly, the concentration of oxygen vacancy Vo may be relatively high in the region of the resistance change layer 116 that is adjacent to the interface with the oxygen vacancy reservoir layer 130.

Additionally, the concentration of the generated oxygen vacancies in the resistance change layer 116 may be proportional to the first set voltage. In an embodiment, the first set voltage may be controlled by adjusting an amplitude of the applied voltage. In another embodiment, the first set voltage may be controlled by adjusting application time of a pulse voltage or the number of times the pulse voltage is applied.

By applying the first set voltage, the concentration of oxygen vacancies within the resistance change layer 116 increases, and as a result, the conductance value of the resistance change layer 116 increases. Because the barrier layer 114 blocks the movement of the oxygen ions and oxygen atoms between the resistance change layer 116 and the base channel layer 112, the conductance of the base channel layer 112 may not change with the application of the first set voltage.

As described with reference to FIG. 2, as the conductance of the resistance change layer 116 increases, the channel conductance of the channel structure 10 increases. Referring to a first graph 501 in FIG. 5, when the first set voltage is maintained from an initial state (a state where time is at S0) to a first time S1, the channel conductance of the channel structure 10 of the semiconductor device 1 increases to peak conductance Gₚ along the first graph 501.

Referring to FIG. 3B, the set operation is terminated by removing the applied first set voltage from the semiconductor device 1. After termination of the set operation, the oxygen vacancies Vo generated inside the resistance change layer 116 diffuse and are redistribute along a concentration gradient within the resistance change layer 116. Referring to the first graph 501 in FIG. 5, when the time for applying the first set voltage reaches the first time S1, the first set voltage is removed. After the first time S1, the oxygen vacancies diffuse, from the region of the resistance change layer 116 adjacent to the interface with the oxygen vacancy reservoir layer 130, to a region away from the interface. The oxygen vacancies Vo diffuse until an equilibrium state or a quasi-equilibrium state is reached in the resistance change layer 116, which then exhibits a uniform distribution of oxygen vacancies. Referring to the first graph 501 in FIG. 5, from the first time S1 until a second time S2 is reached, as the distribution of the oxygen vacancies changes from a denser distribution in the region adjacent to the interface to a uniform distribution throughout the entire resistance change layer 116, the channel conductance of the channel structure 10 decreases.

Referring to the first graph 501 in FIG. 5, when the second time S2 is reached, the resistance change layer 116 reaches an equilibrium state or quasi-equilibrium state with respect to the oxygen vacancies within. Accordingly, after the second time S2, the channel conductance of the channel structure 10 no longer decreases and remains at a target conductance Gₛ₁.

Referring to FIG. 4A, a substrate 101 is grounded, and a second potential V2 of a positive polarity is applied to a gate electrode layer 140, so that a second set voltage is applied between the gate electrode layer 140 and the substrate 101. Along an electric field formed by applying the second set voltage, oxygen inside a channel layer 110 moves to an oxygen vacancy reservoir layer 130 in the form of ions. As oxygen moves from the channel layer 110 to the oxygen vacancy reservoir layer 130, oxygen vacancies Vo are generated inside the channel layer 110.

Referring to a second graph 502 in FIG. 5, while the second set voltage is maintained from an initial state to the first time S1, the channel conductance of the channel layer 110 of a semiconductor device 1a increases to a peak conductance Gₚ along the second graph 502. Referring to FIG. 4A, while applying the second set voltage, the generated oxygen vacancies Vo are distributed in a region within a first depth t4 from an upper surface of the channel layer 110. The peak conductance Gₚ at the first time S1 is obtained by aggregation of the oxygen vacancies in the region of the channel layer 110 adjacent to the interface with the oxygen vacancy reservoir layer 130.

Referring to FIG. 4B, the set operation is terminated by removing the applied second set voltage from the semiconductor device 1a. After termination of the set operation, the oxygen vacancies Vo generated inside the channel layer 110 diffuse throughout the channel layer 110 along an oxygen vacancy concentration gradient and are redistributed within the channel layer 110. Referring to the second graph 502 in FIG. 5, when the time for applying the second set voltage reaches the first time S1, the second set voltage is removed. After the first time S1, the oxygen vacancies diffuse, from the region of the channel layer 110 adjacent to the interface with the oxygen vacancy reservoir layer 130, throughout the layer away from the interface.

Because a thickness t0 of the channel layer 110 of the comparative example of FIGS. 4A and 4B is greater than a thickness t3 of the resistance change layer 116 of FIGS. 3A and 3B, the amount of time taken by the oxygen vacancies to diffuse through the channel layer 110 until reaching an equilibrium state or a quasi-equilibrium state may be longer in the comparative example. Referring to the second graph 502 in FIG. 5, after the first time S1, as the oxygen vacancies diffuse from the region adjacent to the interface with the oxygen vacancy reservoir layer 130 to suffuse the entire channel layer 110, the channel conductance of the channel layer 110 decreases in the comparative example. In the second graph 502 in FIG. 5, by a third time S3, which is after the second time S2 of the first graph 501, the conductance within the channel layer 110 of the comparative example decreases to a target conductance Gₛ₂.

As described above, in the case of the comparative example, the channel layer 110 is a single resistance change material layer with thickness of its channel layer 110 greater than the thickness of the resistance change layer 116 of the channel structure 10 of disclosed embodiments. As a result, in the comparative example the time required to reach the target conductance Gₛ₂ after the removal of the second set voltage is longer compared to a semiconductor device of an embodiment. Although not illustrated in FIG. 5, in the comparative example, a strategy of increasing the application time of the second set voltage to the channel layer 110 to reduce the time to reach the target conductance Gₛ₂ would be countered by an increase in overall the time needed to perform the second set operation compared to the first set operation of the embodiment.

In embodiments of the present disclosure, the change in the concentration of oxygen vacancy according to the set operation occurs in the resistance change layer 116 adjacent to the oxygen vacancy reservoir layer 130 of the channel structure 10. Accordingly, the time for applying the set voltage and the time for the channel conductance of the channel structure 10 to reach the target conductance Gₛ₁ can be shortened, thereby improving the speed of the write operation of the semiconductor device 1. Because the base channel layer 112 has a fixed conductance value regardless of the set operation, the channel structure 10 can maintain a channel conductance value above a predetermined level through a parallel electrical connection with the resistance change layer 116.

As described above, FIG. 3A to FIG. 5 illustrate differences in the distributions and conductance values of the oxygen vacancies of the resistance change layer 116 of embodiments and the channel layer 110 of the comparative example when the set voltages are applied to the semiconductor devices 1 and 1a. Semiconductor devices 1 and 1a may exhibit substantially the same operation mechanisms when reset voltages are respectively applied to the semiconductor devices 1 and 1a. However, the direction of movement of oxygen ions and the diffusion direction of oxygen vacancies when the reset voltage is applied are opposite to the direction of movement of oxygen ions and the diffusion direction of oxygen vacancies when the set voltage is applied.

As described above, semiconductor devices according to embodiments of the present disclosure include a channel structure including a base channel layer, a barrier layer, and a resistance change layer. The resistance change layer has a variable oxygen vacancy concentration and performs oxygen exchange with an oxygen vacancy reservoir layer. Because the barrier layer suppresses movement of the oxygen vacancies between the base channel layer and the resistance change layer, the base channel layer can have a fixed oxygen vacancy concentration. As a result, the resistance change layer can have variable conductance, and the base channel layer can exhibit invariable conductance.

According to embodiments of the present disclosure, during a write operation of a semiconductor device, a change in the concentration of the oxygen vacancy can be controlled in the resistance change layer adjacent to the oxygen vacancy reservoir layer of the channel structure. Accordingly, the write speed of the semiconductor device, which depends on movement speed and distribution state of the oxygen vacancies, can be improved. The base channel layer has fixed conductance, thereby helping the channel structure to maintain channel conductance above a pre-selected level. As a result, it is possible to provide a semiconductor device having an improved write speed and an improved level of channel conductance.

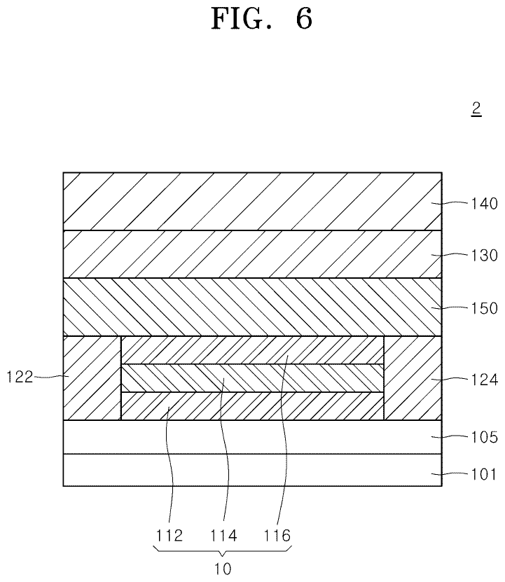

FIG. 6 is a cross-sectional view schematically illustrating a semiconductor device according to another embodiment of the present disclosure. Referring to FIG. 6, as compared to a semiconductor device 1 of FIG. 1, a semiconductor device 2 further includes an electrolyte layer 150. A configuration of the semiconductor device 2 excluding the electrolyte layer 150 is substantially the same as the configuration of the semiconductor device 1 in FIG. 1.

Referring to FIG. 6, the electrolyte layer 150 is disposed between a channel structure 10 and an oxygen vacancy reservoir layer 130. In an embodiment, the electrolyte layer 150 is disposed to cover upper surfaces of a source electrode layer 122, a resistance change layer 116, and a drain electrode layer 124. The electrolyte layer 150 is configured to selectively allow oxygen ions to pass between the resistance change layer 116 and the oxygen vacancy reservoir layer 130.

When a set voltage or a reset voltage is applied, and a set operation or a reset operation is performed, oxygen moves in the form of ions through the electrolyte layer 150. When the applied set voltage or reset voltage is removed and the set operation or the reset operation is terminated, however, movement of oxygen ions is reduced in the absence of an applied electrical voltage, and thus, the passing of oxygen ions through the electrolyte layer 150 to reach the oxygen vacancy reservoir layer 130 or the resistance change layer 116 is suppressed. As a result, the electrolyte layer 150 inhibits the movement of the oxygen after the set operation or the reset operation is terminated, thereby supporting the stability of oxygen vacancy concentration within the resistance change layer 116.

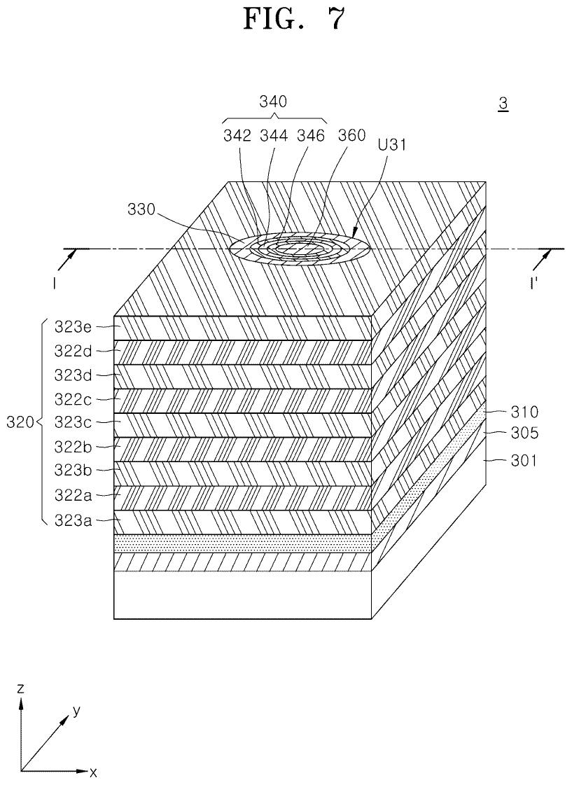

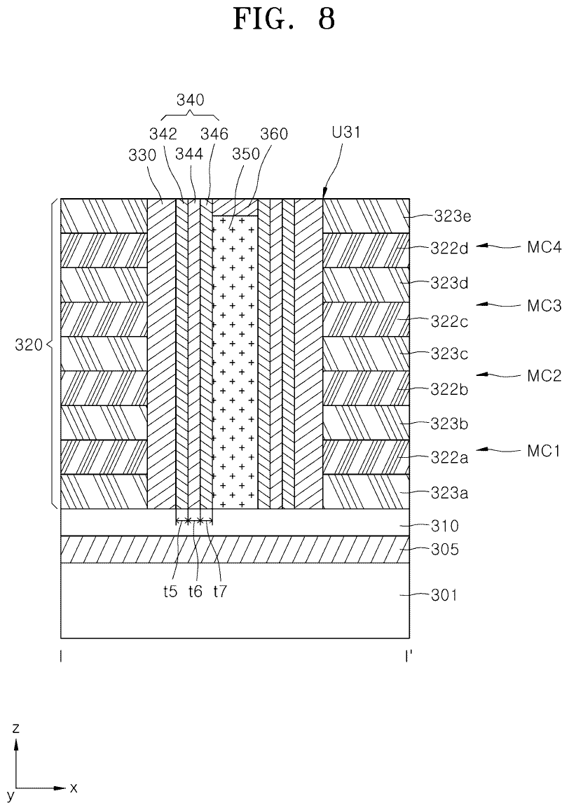

FIG. 7 is a perspective view schematically illustrating a semiconductor device according to another embodiment of the present disclosure. FIG. 8 is a cross-sectional view of a semiconductor device of FIG. 7 taken along a line I-I′.

Referring to FIG. 7 and FIG. 8, a semiconductor device 3 includes a substrate 301 and a gate structure 320 disposed over the substrate 301. The semiconductor device 3 includes a hole pattern U31 penetrating the gate structure 320 over the substrate 301. The semiconductor device 3 includes an oxygen vacancy reservoir layer 330 that covers a sidewall surface of the gate structure 320 inside or within the hole pattern U31, and a channel structure 340 disposed adjacent to the oxygen vacancy reservoir layer 330 in a lateral direction, for example, in the x-direction and y-direction inside or within the hole pattern U31. The channel structure 340 contacts the oxygen vacancy reservoir layer 330. The channel structure 340 includes a resistance change layer 342, a barrier layer 344, and a base channel layer 346 that are arranged sequentially.

The semiconductor device 3 further includes a channel lower contact layer 310 that is in contact with one end of the channel structure 340 over the substrate 301. The channel lower contact layer 310 is electrically connected to a source electrode (not illustrated). In addition, the semiconductor device 3 includes a channel upper contact layer 360 that is in contact with the other end of the channel structure 340. The other end of the channel structure 340 is positioned opposite to the end connected to the source electrode, in a direction perpendicular to an upper surface of the substrate 301, that is, in the z-direction. The channel upper contact layer 360 is electrically connected to a drain electrode (not illustrated). A source-drain voltage may be applied to the channel structure 340 by potentials provided by the source electrode and the drain electrode.

Referring to FIG. 7 and FIG. 8, the substrate 301 includes a conductor, a semiconductor, or an insulator capable of being subjected to semiconductor integration processes. In an embodiment, the substrate 301 is a semiconductor substrate. Specifically, the semiconductor substrate includes, for example, silicon (Si), germanium (Ge), gallium arsenide (GaAs), molybdenum selenide (MoSe₂), hafnium selenide (HfSe₂), indium selenide (InSe), gallium selenide (GaSe), black phosphorous, indium-gallium-zinc oxide (IGZO), or a combination of two or more thereof. The semiconductor substrate may be doped with a dopant. The semiconductor substrate may be doped, for example, with an N-type dopant or a P-type dopant.

A base insulating layer 305 is disposed on the substrate 301. The base insulating layer 305 electrically insulates the substrate 301 and the channel lower contact layer 310 from each other. The base insulating layer 305 includes an insulating material. The insulating material includes, for example, oxide, nitride, oxynitride, or a combination of two or more thereof.

The channel lower contact layer 310 is disposed on the base insulating layer 305. The channel lower contact layer 310 is electrically connected to the channel structure 340. The channel lower contact layer 310 includes a conductive material. The conductive material includes, for example, a doped semiconductor, metal, conductive metal nitride, conductive metal carbide, conductive metal silicide, or a conductive metal oxide. The conductive material includes, for example, silicon (Si) doped with an n-type or p-type dopant, tungsten (W), titanium (Ti), copper (Cu), aluminum (Al), ruthenium (Ru), platinum (Pt), iridium (Ir), iridium oxide, tungsten nitride, titanium nitride, tantalum nitride, tungsten carbide, titanium carbide, tungsten silicide, titanium silicide, tantalum silicide, ruthenium oxide, or a combination of two or more thereof.

The gate structure 320 is disposed on the channel lower contact layer 310. The gate structure 320 includes first to fourth gate electrode layers 322a, 322b, 322c, and 322d and first to fifth interlayer insulating layers 323a, 323b, 323c, 323d, and 323e, which are alternately stacked along the z-direction. The first interlayer insulating layer 323a is disposed to be in contact with the channel lower contact layer 310. The fifth interlayer insulating layer 323e is disposed at an uppermost layer of the gate structure 320.

Each of the first to fourth gate electrode layers 322a, 322b, 322c, and 322d includes a conductive material. The conductive material includes, for example, a doped semiconductor, metal, conductive metal nitride, conductive metal carbide, conductive metal silicide, or conductive metal oxide. The conductive material includes, for example, silicon (Si) doped with an n-type dopant or a p-type dopant, tungsten (W), titanium (Ti), copper (Cu), aluminum (Al), ruthenium (Ru), platinum (Pt), iridium (Ir), iridium oxide, tungsten nitride, titanium nitride, tantalum nitride, tungsten carbide, titanium carbide, tungsten silicide, titanium silicide, tantalum silicide, ruthenium oxide or a combination of two or more thereof. Each of the first to fifth interlayer insulating layers 323a, 323b, 323c, 323d, and 323e includes an insulating material. The insulating material includes, for example, oxide, nitride, oxynitride, or a combination of two or more thereof.

In some embodiments, the number of gate electrode layers of the gate structure 320 is not necessarily limited to four. The gate electrode layers may be arranged in various numbers, alternating with interlayer insulating layers that insulate the various numbers of gate electrode layers from each other along the z-direction.

Referring to FIG. 7 and FIG. 8, the hole pattern U31 is formed to penetrate the gate structure 320 through to the channel lower contact layer 310. In an embodiment, the hole pattern U31 is formed by photolithography and etching processes in a semiconductor integration process. The hole pattern U31 exposes a sidewall surface of the gate structure 320. That is, inside or within the hole pattern U31, side surfaces of the first to fourth gate electrode layers 322a, 322b, 322c, and 322d and side surfaces of the first to fifth interlayer insulating layers 323a, 323b, 323c, 323d, and 323e are exposed.

Referring to FIG. 7 and FIG. 8, the oxygen vacancy reservoir layer 330 is disposed along the side surface of the gate structure 320 inside or within the hole pattern U31. The oxygen vacancy reservoir layer 330 is disposed to be in contact with the side surfaces of the first to fourth gate electrode layers 322a, 322b, 322c, and 322d and the side surfaces of the first to fifth interlayer insulating layers 323a, 323b, 323c, 323d, and 323e.

The oxygen vacancy reservoir layer 330 includes oxide containing oxygen vacancies. The oxygen vacancy reservoir layer 330 includes, for example, gadolinium oxide (GdOₓ(0<x≤1)), molybdenum oxide (MoOₓ(0<x≤1)), tungsten oxide (WO₃₋ₓ(0<x≤1)), copper oxide (CuO), titanium oxide (TiO₂), or a combination of two or more thereof.

The oxygen vacancy reservoir layer 330 exchanges oxygen vacancies with the resistance change layer 342 of the channel structure 340 while a write operation, such as a set operation or a reset operation, is in progress. As an example, a set operation is performed by applying a set voltage between at least one of the first to fourth gate electrode layers 322a, 322b, 322c, and 322d and the channel structure 340. When the set operation is performed, the oxygen vacancy reservoir layer 330 provides the oxygen vacancies to a region of the resistance change layer 342 that overlaps the corresponding gate electrode layer in the horizontal direction (e.g., x-direction or y-direction), thereby increasing the concentration of oxygen vacancies in the region of the resistance change layer 342. As another example, the reset operation is performed by applying a reset voltage between at least one of the first to fourth gate electrode layers 322a, 322b, 322c, and 322d and the channel structure 340. When the reset operation is performed, the oxygen vacancy reservoir layer 330 receives oxygen vacancies from the region of the resistance change layer 342 that overlaps the corresponding gate electrode layer in the horizontal direction, thereby decreasing the concentration of oxygen vacancy in the region of the resistance change layer 342.

Referring to FIG. 7 and FIG. 8, the channel structure 340 is disposed within the hole pattern U31. The channel structure 340 includes the resistance change layer 342, the barrier layer 344, and the base channel layer 346.

The resistance change layer 342 is in contact with the oxygen vacancy reservoir layer 330, which is disposed along the sidewall surface of the gate structure 320. The resistance change layer 342 includes oxygen vacancies. As an example, the resistance change layer 342 includes metal oxide containing the oxygen vacancies. Material characteristics of the resistance change layer 342 may be substantially the same as that of the resistance change layer 116 of a semiconductor device 1 described with reference to FIG. 1. The resistance change layer 342 has a thickness t5 of, for example, 1 nm to 3 nm. The thickness t5 of the resistance change layer 342 may be smaller than a thickness t7 of the base channel layer 346.

The barrier layer 344 is in contact with the resistance change layer 342. The barrier layer 344 functions to suppress movement of the oxygen between the resistance change layer 342 and the base channel layer 346. The barrier layer 344 inhibits oxygen from passing through the barrier layer 344 in the form of ions or atoms. The material characteristics of the barrier layer 344 may be substantially the same as the material characteristics of the barrier layer 114 of the semiconductor device 1 described with reference to FIG. 1. The barrier layer 344 has a thickness t6 of, for example, 3 nm to 10 nm.

The base channel layer 346 is in contact with the barrier layer 344. The base channel layer 346 includes oxygen vacancies. The concentration of the oxygen vacancies in the base channel layer 346 may not change throughout the write operation of the semiconductor device 3, as compared to the resistance change layer 342.

The base channel layer 346 includes metal oxide including oxygen vacancies. The base channel layer 346 includes substantially the same material as the resistance change layer 342. The material characteristics of the base channel layer 346 may be substantially the same as the material characteristics of the base channel layer 112 of the semiconductor device 1 described with reference to FIG. 1. The base channel layer 346 has a thickness t7 of, for example, 1 nm to 10 nm.

As described above, when a set voltage or a reset voltage is applied between at least one of the first to fourth gate electrode layers 322a, 322b, 322c, and 322d and the channel structure 340, a region of the resistance change layer 342 exchanges oxygen vacancies with the oxygen vacancy reservoir layer 330. After the set voltage or the reset voltage is removed, the conductance of the resistance change layer 342 is determined in proportion to the concentration of the oxygen vacancies remaining in the region of the resistance change layer 342. On the other hand, in the base channel layer 346, exchange of the oxygen vacancies with the resistance change layer 342 is suppressed by the barrier layer 344. Accordingly, the exchange of the oxygen vacancies with the oxygen vacancy reservoir layer 330 via the resistance change layer 342 is inhibited in the case of the base channel layer 346. Accordingly, the base channel layer 346 can have an invariable concentration of oxygen vacancies regardless of the application of the set voltage or the reset voltage. The base channel layer 346 can have a fixed conductance value due to the invariable concentration of oxygen vacancies.

Referring to FIG. 8, a filling insulating layer 350 is disposed in the hole pattern U31 in which the oxygen vacancy reservoir layer 330 and the channel structure 340 are disposed. The filling insulating layer 350 includes, for example, oxide, nitride, oxynitride, or a combination of two or more thereof.

The channel upper contact layer 360 is disposed on the filling insulating layer 350 within the hole pattern U31. The channel upper contact layer 360 is in contact with the base channel layer 346. The channel upper contact layer 360 is electrically connected to the drain electrode (not illustrated). In some embodiments, the channel upper contact layer 360 may be disposed outside the hole pattern U31. As an example, the channel upper contact layer 360 may be disposed over the hole pattern U31 to cover an upper surface of the channel structure 340.

The channel upper contact layer 360 includes a conductive material. The conductive material includes, for example, a doped semiconductor, metal, conductive metal nitride, conductive metal carbide, conductive metal silicide, or conductive metal oxide. The conductive material includes, for example, silicon (Si) doped with an n-type dopant, tungsten (W), titanium (Ti), copper (Cu), aluminum (Al), ruthenium (Ru), platinum (Pt), iridium (Ir), iridium oxide, tungsten nitride, titanium nitride, tantalum nitride, tungsten carbide, titanium carbide, tungsten silicide, titanium silicide, tantalum silicide, ruthenium oxide or a combination of two or more thereof.

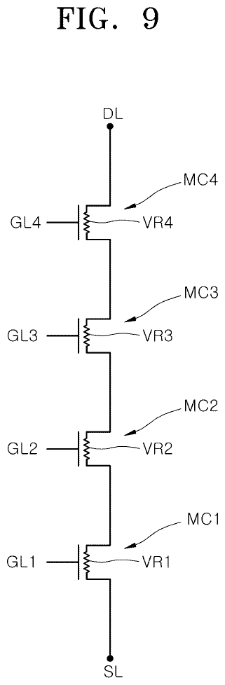

FIG. 9 is a circuit diagram of a semiconductor device according to an embodiment of the present disclosure. FIG. 9 may be a circuit diagram of a semiconductor device 3 described above with reference to FIG. 7 and FIG. 8. Referring to FIG. 9, a semiconductor device includes first to fourth memory cells MC1, MC2, MC3, and MC4 connected in series in a NAND form.

Referring to FIG. 9, the first to fourth memory cells MC1, MC2, MC3, and MC4 are connected in series in a form of a string between a source electrode SL and a drain electrode DL. Each of the first to fourth memory cells MC1, MC2, MC3, and MC4 includes a transistor-type memory element. The first to fourth memory cells MC1, MC2, MC3, and MC4 include first to fourth variable resistance elements VR1, VR2, VR3, and VR4 disposed between gate electrodes GL1, GL2, GL3, and GL4, and a channel of the transistor, respectively.

In FIG. 7 and FIG. 8, a channel lower contact layer 310 and a channel upper contact layer 360 correspond to the source electrode SL and the drain electrode DL in FIG. 9, respectively. First to fourth gate electrode layers 322a, 322b, 322c, and 322d in FIG. 7 and FIG. 8 correspond to the first to fourth gate electrodes GL1, GL2, GL3, and GL4 in FIG. 9, respectively. Regions of the oxygen vacancy reservoir layer 330 and regions of channel structure 340, which are adjacent to the first to fourth gate electrode layers 322a, 322b, 322c, and 322d in FIG. 7 and FIG. 8 respectively, may constitute the first to fourth variable resistance elements VR1, VR2, VR3, and VR4 in FIG. 9. A write operation for the semiconductor device may be performed through a set operation and a reset operation for at least one memory cell from among the first to fourth memory cells MC1, MC2, MC3, and MC4.

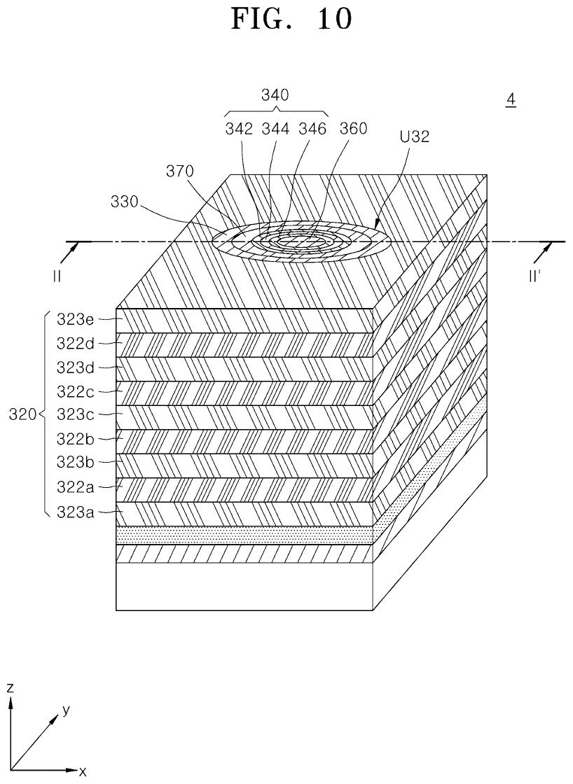

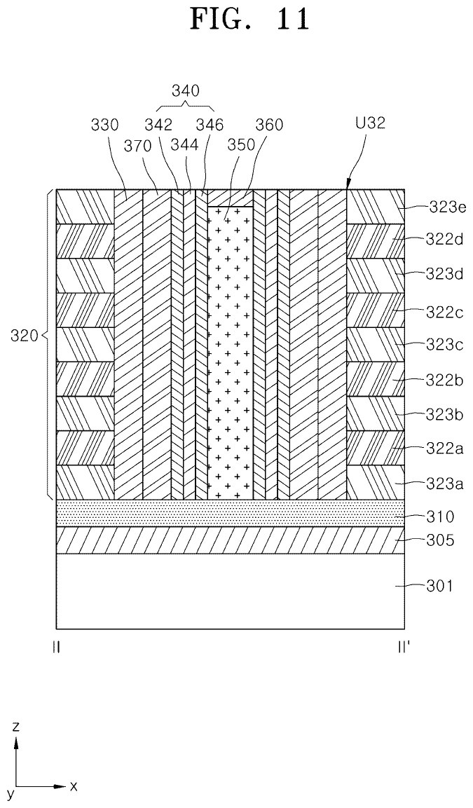

FIG. 10 is a perspective view schematically illustrating a semiconductor device according to another embodiment of the present disclosure. FIG. 11 is a cross-sectional view of the semiconductor device of FIG. 10 taken along a line II-II′.

A semiconductor device 4 in FIG. 10 and FIG. 11 further includes an electrolyte layer 370, as compared to a semiconductor device 3 of FIG. 7 and FIG. 8. A configuration of the semiconductor device 4 excluding the electrolyte layer 370 is substantially the same as the configuration of the semiconductor device 3 in FIG. 7 and FIG. 8.

Referring to FIG. 10 and FIG. 11, the electrolyte layer 370 is disposed between an oxygen vacancy reservoir layer 330 and a channel structure 340. In an embodiment, the electrolyte layer 370 extends in the z-direction along a sidewall surface of the gate structure 320. The electrolyte layer 370 is configured to selectively allow oxygen ions to pass between the oxygen vacancy reservoir layer 330 and a resistance change layer 342.

When a set voltage or a reset voltage is applied and a set operation or a reset operation is performed, oxygen moves in the form of ions through the electrolyte layer 370. When the applied set voltage or the reset voltage is removed and the set operation or the reset operation is terminated, however, movement of oxygen in the form of movable ions is reduced in the absence of an applied electrical voltage, and thus, the passing of oxygen ions through the electrolyte layer 150 to reach the oxygen vacancy reservoir layer 330 or the resistance change layer 342 is suppressed. As a result, the electrolyte layer 370 inhibits the movement of the oxygen after the set operation or the reset operation is terminated, thereby supporting the stability of oxygen vacancy concentration within the resistance change layer 342.

As described above, according to embodiments of the present disclosure, a semiconductor device having a three-dimensional structure includes a gate structure including a plurality of gate electrode layers and a plurality of interlayer insulating layers alternately stacked. In addition, the semiconductor device includes a channel structure including a base channel layer, a barrier layer, and a resistance change layer, which extend in a direction perpendicular to a surface of a substrate.

The base channel layer has an invariable oxygen vacancy concentration and exhibits invariable conductance. The resistance change layer has a variable oxygen vacancy concentration through oxygen exchange with the oxygen vacancy reservoir layer and exhibits variable conductance. The barrier layer suppresses movement of the oxygen vacancies between the base channel layer and the resistance change layer.

According to embodiments of the present disclosure, during a write operation of the semiconductor devices, a change in the concentration of oxygen vacancy can be controlled in the resistance change layer adjacent to the oxygen vacancy reservoir layer of the channel structure. Accordingly, write speeds of the semiconductor devices, which depend on the movement speed and distribution state of the oxygen vacancies, can be improved. The base channel layer has a fixed conductance value, thereby helping the channel structure maintain channel conductance above a predetermined level. As a result, semiconductor devices with improved write speed and channel conductance can be provided.

According to embodiments of the present disclosure, during a set operation or a reset operation for a semiconductor device, the concentration of the oxygen vacancies in the resistance change layer can be controlled by controlling the set voltage or the reset voltage. Because the conductance of the resistance change layer increases in proportion to the concentration of the oxygen vacancies, a plurality of conductance values corresponding to multi-level signal information can be written in the channel structure.

In some embodiments, the semiconductor devices include a plurality of cell arrays and may be used in an analog computation in memory (AciM) device. As an example, the semiconductor device may be applied to cells of a cell array device that stores continuous weights and performs a vector matrix multiplication operation. The weights may correspond to the plurality of conductance values of the channel structure. Accordingly, the semiconductor devices may be utilized in a memristor-based synaptic element in neuromorphic technology.

In embodiments of the present disclosure, a plurality of memory cells having a three-dimensional structure connected in a NAND form are disclosed, but the present disclosure is not necessarily limited thereto, and a plurality of memory cells having a three-dimensional structure connected in a NOR form may also be configured. In this manner, semiconductor devices according to embodiments of the present disclosure may include memory cells having various forms of three-dimensional structures.

Concepts are disclosed in conjunction with various examples and embodiments. Those skilled in the art will understand that various modifications, additions, and substitutions are possible without departing from the scope and technical concepts of the present disclosure. The embodiments disclosed in the present specification should be considered from an illustrative standpoint and not considered a restrictive standpoint. The scope of the present disclosure is not limited to the descriptions, and all distinctive features within an equivalent scope should be construed as included in the present disclosure. All changes within the meaning and range of equivalency of the claims are included within their scope.

What is claimed is:

1. A semiconductor device comprising:
a substrate;
a channel structure disposed over the substrate, the channel structure comprising a base channel layer, a barrier layer, and a resistance change layer sequentially disposed over the substrate;
a source electrode layer and a drain electrode layer respectively disposed at opposite ends of the channel structure;
an oxygen vacancy reservoir layer disposed on the channel structure; and
a gate electrode layer disposed on the oxygen vacancy reservoir layer.

2. The semiconductor device of claim 1,
wherein the base channel layer has invariable conductance, and wherein the resistance change layer has variable conductance.

3. The semiconductor device of claim 1, wherein the resistance change layer and the base channel layer include the same material.

4. The semiconductor device of claim 1,
wherein the resistance change layer is configured to exchange oxygen vacancies with the oxygen vacancy reservoir layer, and
wherein the barrier layer is configured to suppress an exchange of oxygen vacancies between the resistance change layer and the base channel layer.

5. The semiconductor device of claim 1,
wherein the resistance change layer has a high resistance state and a low resistance state that are distinguishable from each other;
wherein a conductance of the resistance change layer in the high resistance state is substantially equal to a conductance of the base channel layer; and
wherein a conductance of the resistance change layer in the low resistance state is 10 to 100 times greater than the conductance of the base channel layer.

6. The semiconductor device of claim 1, wherein a thickness of the resistance change layer is smaller than a thickness of the base channel layer.

7. The semiconductor device of claim 1,
wherein the resistance change layer has a thickness of 1 nm to 3 nm;
wherein the barrier layer has a thickness of 3 nm to 10 nm; and
wherein the base channel layer has a thickness of 1 nm to 10 nm.

8. The semiconductor device of claim 1, wherein the resistance change layer comprises at least one selected from the group consisting of tungsten oxide (WO₃), molybdenum oxide (MoO₃), selenium oxide (CeO₃), iron oxide (Fe₃O₄), zirconium oxide (ZrO₂), cobalt oxide (CoO), vanadium oxide (V₂O₅), titanium oxide (TiO₂), strontium titanium oxide (SrTiO₃), yttrium oxide (Y₂O₃), and indium gallium zinc oxide (InGaZnO).

9. The semiconductor device of claim 1, wherein the barrier layer comprises at least one selected from the group consisting of silicon oxide, silicon nitride, silicon oxynitride, aluminum oxide, and aluminum nitride.

10. The semiconductor device of claim 1, further comprising an electrolyte layer disposed between the channel structure and the oxygen vacancy reservoir layer.

11. The semiconductor device of claim 10, wherein the electrolyte layer comprises at least one selected from the group consisting of hafnium oxide (HfO₂), zirconium oxide (ZrO₂), yttria-stabilized zirconia (YSZ), oxide of barium-selenium-yttrium (Ba—Ce—Y—O), and oxide of zirconium-scandium (Zr—Sc—O).

12. The semiconductor device of claim 1, wherein the oxygen vacancy reservoir layer comprises at least one selected from the group consisting of gadolinium oxide (GdOₓ(0<x≤1)), molybdenum oxide (MoOₓ(0<x≤1)), tungsten oxide (WO₃₋ₓ(0<x≤1)), copper oxide (CuO), and titanium oxide (TiO₂).

13. A semiconductor device comprising:
a substrate;
a gate structure disposed over the substrate, the gate structure comprising at least one gate electrode layer and at least one interlayer insulating layer that are alternately stacked;
a hole pattern penetrating the gate structure, the hole pattern exposing a sidewall surface of the gate structure;
an oxygen vacancy reservoir layer disposed within the hole pattern, the oxygen vacancy reservoir layer covering the sidewall surface of the gate structure; and
a channel structure disposed within the hole pattern, the channel structure contacting the oxygen vacancy reservoir layer,
wherein the channel structure comprises a base channel layer, a barrier layer, and a resistance change layer, which are sequentially disposed on the oxygen vacancy reservoir layer.

14. The semiconductor device of claim 13,
wherein the resistance change layer is configured to exchange oxygen vacancies with the oxygen vacancy reservoir layer; and
wherein the barrier layer is configured to suppress an exchange of the oxygen vacancies between the resistance change layer and the based channel layer.

15. The semiconductor device of claim 13,
wherein the base channel layer has invariable conductance, and wherein the resistance change layer has variable conductance.

16. The semiconductor device of claim 13, wherein a thickness of the resistance change layer is smaller than a thickness of the base channel layer.

17. The semiconductor device of claim 13, wherein the resistance change layer and the base channel layer include the same material.

18. The semiconductor device of claim 13, further comprising an electrolyte layer disposed between the channel structure and the oxygen vacancy reservoir layer.

19. The semiconductor device of claim 13, further comprising:
a channel lower contact layer in contact with one end of the channel structure disposed over the substrate; and
a channel upper contact layer in contact with an opposite end of the channel structure, in a direction perpendicular to a surface of the substrate.

20. The semiconductor device of claim 13, wherein the barrier layer comprises at least one selected from the group consisting of silicon oxide, silicon nitride, silicon oxynitride, aluminum oxide, and aluminum nitride.
